(19) United States
(12) Patent Application Publication
(10) Pub. No.: US 2026/0173711 A1
(43) Pub. Date: Jun. 18, 2026

(54) DISPLAY APPARATUS

(71) Applicant: LG Display Co., Ltd., Seoul (KR)

(72) Inventors: Jungseop YOON, Chilgok-gun (KR); Wooseok CHO, Gumi-si (KR)

(73) Assignee: LG Display Co., Ltd., Seoul (KR)

(21) Appl. No.: 19/209,297

(22) Filed: May 15, 2025

(30) Foreign Application Priority Data
Dec. 17, 2024 (KR) 10-2024-0188792

(51) Int. Cl. H10K 59/50; H10H 29/32; H10H 29/49; H10H 29/852; H10H 29/855; H10K 59/121; H10K 59/131; H10K 59/40; H10K 59/80

(52) U.S. Cl. CPC H10K 59/50; H10H 29/32; H10H 29/49; H10H 29/855; H10K 59/1213; H10K 59/131; H10K 59/40; H10K 59/879; H10H 29/852; H10K 59/873

(57) ABSTRACT

A display apparatus in some examples can include a substrate having a plurality of sub-pixels defined, a plurality of light-emitting elements disposed in each of the plurality of sub-pixels, an encapsulating layer disposed on the plurality of light-emitting elements, a plurality of optical members disposed on the encapsulating layer for each of the plurality of sub-pixels, a plurality of first transistors disposed on the encapsulating layer, a plurality of second transistors disposed on the encapsulating layer, a plurality of first driving electrodes connected to the plurality of first transistors on the encapsulating layer and in contact with one side of the plurality of optical members, and a plurality of second driving electrodes connected to the plurality of second transistors on the encapsulating layer and in contact with another side of the plurality of optical members.

### CROSS-REFERENCE TO RELATED APPLICATIONS

This application claims priority to Korean Patent Application No. 10-2024-0188792 filed on Dec. 17, 2024, in the Korean Intellectual Property Office, the entire disclosure of which is hereby expressly incorporated by reference into the present application.

### BACKGROUND

### Field

The present disclosure relates to an apparatus and particularly to, for example, without limitation, a display apparatus and more particularly, to a display apparatus capable of facilitating viewing angle control.

### Description of the Related Art

As technology in modern society develops, display apparatus are used in various ways to provide information to users. Display apparatus are included in electronic signs that simply transmit visual information in one direction, as well as various electronic apparatuses that use higher technology to confirm a user input and provide information in response to the confirmed input.

For example, a display apparatus can be included in vehicles to provide various information to a driver and passengers of the vehicle.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

The inventors of the present disclosure have recognized that the display apparatus of a vehicle needs to display content appropriately so as not to interfere with vehicle operations. For example, the display apparatus needs to limit display of content that can distract a driver of the vehicle or reduce concentration on driving while the vehicle is in operation.

An object of the present disclosure is to provide a display apparatus capable of providing content with a limited viewing angle depending on the driving mode.

Another object of the present disclosure is to provide a display apparatus with an improved side viewing angle depending on the driving mode.

Still another object of the present disclosure is to provide a display apparatus capable of controlling the shape of an optical structure according to an electrical signal.

Objects of the present disclosure are not limited to the above-mentioned objects, and other objects, which are not mentioned above, can be clearly understood by those skilled in the art from the following descriptions.

According to an aspect of the present disclosure, there is provided a display apparatus. The display apparatus in some aspects of the present disclosure comprises a substrate having a plurality of sub-pixels defined, a plurality of light-emitting elements disposed in each of the plurality of sub-pixels, an encapsulating layer disposed on the plurality of light-emitting elements, a plurality of optical members disposed on the encapsulating layer for each of the plurality of sub-pixels, a plurality of first transistors disposed on the encapsulating layer, a plurality of second transistors disposed on the encapsulating layer, a plurality of first driving electrodes connected to the plurality of first transistors on the encapsulating layer and in contact with one side of the plurality of optical members, and a plurality of second driving electrodes connected to the plurality of second transistors on the encapsulating layer and in contact with another side of the plurality of optical members.

According to another aspect of the present disclosure, there is provided a display apparatus. The display apparatus in some aspects of the present disclosure comprises a substrate having a plurality of sub-pixels defined, a plurality of light-emitting elements disposed in each of the plurality of sub-pixels, a plurality of first driving electrodes disposed on one side of the plurality of light-emitting elements on the plurality of light-emitting elements, a plurality of second driving electrodes disposed on another side of the plurality of light-emitting elements on the plurality of light-emitting elements, and a plurality of optical members covering a portion of top surfaces of the plurality of first driving electrodes and a portion of top surfaces of the plurality of second driving electrodes, and configured to shift their shapes one side or another side depending on a voltage applied to the plurality of first driving electrodes and the plurality of second driving electrodes.

Other detailed matters of the example embodiments of the present disclosure are included in the detailed description and the drawings.

Aspects of the present disclosure can selectively control the side viewing angle.

Aspects of the present disclosure can enable process optimization because the viewing angle can be controlled without additionally disposing separate pixels that limit the viewing angle.

Aspects of the present disclosure can allow the shape of the optical member to be varied depending on an eye position of a driver and/or passenger, thereby selectively providing different images to the driver and passenger.

Aspects of the present disclosure can reduce a manufacturing process and manufacturing cost of the display apparatus by controlling the shape of an optical structure according to an electrical signal.

The effects according to the present disclosure are not limited to the contents exemplified above, and more various effects are included in the present disclosure.

It is to be understood that both the foregoing general description and the following detailed description are examples and explanatory and are intended to provide further explanation of the inventive concepts as claimed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an example view of a display apparatus according to one or more example embodiments of the present disclosure;

FIG. 2 is a block diagram of the display apparatus according to one or more example embodiments of the present disclosure;

FIG. 3 is a plan view of the display apparatus according to one example embodiment of the present disclosure;

FIG. 4 is an enlarged plan view of a pixel area of the display apparatus according to one example embodiment of the present disclosure;

FIG. 5 is a cross-sectional view taken along line A-A′ of FIG. 4;

FIG. 6 is a cross-sectional view illustrating the display apparatus according to a first driving mode of the present disclosure; and

FIG. 7 is a cross-sectional view illustrating the display apparatus according to a second driving mode of the present disclosure.

### DETAILED DESCRIPTION OF THE EMBODIMENTS

Advantages and characteristics of the present disclosure and a method of achieving the advantages and characteristics will be clear by referring to example embodiments of the present disclosure described below in detail together with the accompanying drawings. However, the present disclosure is not limited to the example embodiments disclosed herein but will be implemented in various forms. The example embodiments of the present disclosure are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments of the present disclosure can be carried out independently of or in association with each other.

Throughout the drawings and the detailed description, unless otherwise described, the same drawing reference numerals should be understood to refer to the same elements, features, and structures. The relative size and depiction of these elements can be exaggerated for clarity, illustration, and convenience. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the disclosure and can be thus different from those used in actual products.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

Further, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements can be so disposed to directly contact each other, or can be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments of the present disclosure belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Rather, these embodiments of the present disclosure can be provided so that this disclosure can be sufficiently thorough and complete to assist those skilled in the art to fully understand the scope of the present disclosure.

Hereinafter, example embodiments of the present disclosure will be described in detail with reference to the drawings. All the components of each display apparatus according to all embodiments of the present disclosure are operatively coupled and configured.

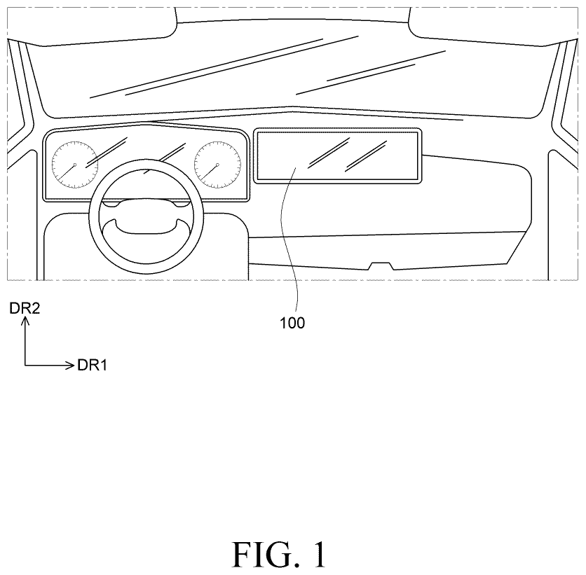

FIG. 1 is an example view of a display apparatus according to one or more embodiments of the present disclosure.

Referring to FIG. 1, a display apparatus 100 can be disposed on at least a portion of a dashboard of a vehicle. The dashboard of the vehicle can include a configuration that is disposed in front of a front seat (for example, driver's seat, passenger seat) of the vehicle. For example, the dashboard of the vehicle can have input configurations disposed for operating various functions (for example, air conditioning, audio system, navigation system) inside the vehicle.

The display apparatus 100 can be disposed on the dashboard of a vehicle and can function as an input unit for operating at least some of various functions of the vehicle. The display apparatus 100 can provide various information related to the vehicle, for example, vehicle operation information (for example, current speed of the vehicle, remaining fuel amount, driving distance), information on vehicle parts (for example, damage to vehicle tires), or the like.

The display apparatus 100 can be disposed to span across the driver's seat and the passenger seat disposed in the front seats of the vehicle. For example, the display apparatus 100 can extend along a first direction DR1. Users of the display apparatus 100 can include the driver of the vehicle and a passenger sitting in the passenger seat. Both the driver and the passenger of the vehicle can use the display apparatus 100.

The display apparatus 100 illustrated in FIG. 1 can illustrate a portion of the display apparatus. The display apparatus 100 illustrated in FIG. 1 can illustrate a display panel among various components included in the display apparatus 100. Specifically, for example, the display apparatus 100 illustrated in FIG. 1 can illustrate at least a portion of a display area and a non-display area of the display panel. Configurations of the display apparatus 100 other than the configuration illustrated in FIG. 1 can be mounted inside (or at least a portion of) the vehicle.

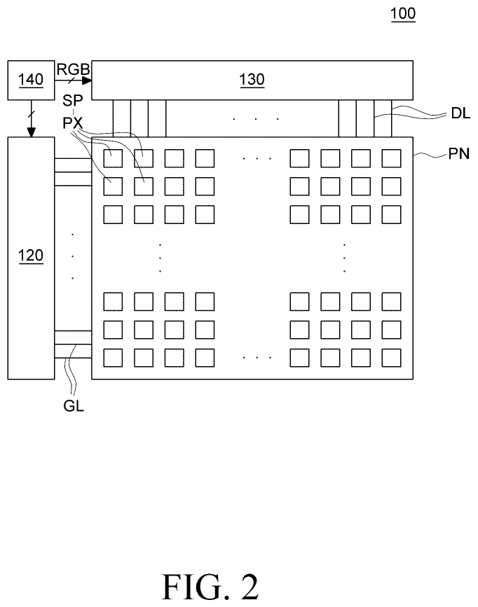

FIG. 2 is a functional block diagram of the display apparatus according to one or more example embodiments of the present disclosure.

An electroluminescent display apparatus can be applied as the display apparatus according to one example embodiment of the present disclosure. The electroluminescent display apparatus can be an organic light emitting diode (OLED) display apparatus, a quantum-dot light emitting diode (QD) display apparatus, or an inorganic light emitting diode (ILD) display apparatus.

Referring to FIG. 2, the display apparatus 100 can include a display panel PN, a data driving circuit DD, a gate driving circuit GD, and a timing controller TD.

The display panel PN can generate an image to be provided to a user. For example, the display panel PN can generate and display an image to be provided to a user through a plurality of pixels PX each having a pixel circuit disposed therein.

The data driving circuit DD, the gate driving circuit GD, and the timing controller TD can provide signals for the operation of each pixel PX through signal lines. For example, signal lines for providing signals for the operation of each pixel PX can include a plurality of data lines DL and a plurality of gate lines GL.

The plurality of data lines DL is disposed in a column direction and can include a plurality of lines connected to pixels PX disposed in one column direction, and the plurality of gate lines GL is disposed in a row direction and can include a plurality of lines connected to pixels PX disposed in one row direction.

In some cases, the display apparatus 100 can further include a power unit. In this case, a signal for the operation of the pixel PX can be provided through a power line connecting the power unit and the display panel PN. In some example embodiments of the present disclosure, the power unit can provide power to the data driving circuit DD and the gate driving circuit GD. The data driving circuit DD and the gate driving circuit GD can be driven based on the power provided from the power unit.

For example, the data driving circuit DD can apply the data signal to each pixel PX through a plurality of data lines DL, the gate driving circuit GD can apply the gate signal to each pixel PX through the plurality of gate lines GL, and the power unit can supply the power voltage to each pixel PX through a power voltage supply line.

The timing controller TD can control the data driving circuit DD and the gate driving circuit GD. For example, the timing controller TD can rearrange digital video data input from the outside to match the resolution of the display panel PN and supply the digital video data to the data driving circuit DD.

The data driving circuit DD can convert digital video data input from the timing controller TD into analog data voltage based on the data control signal and supply the converted analog data voltage to the plurality of data lines DL.

The gate driving circuit GD can generate a scan signal and a light emission signal based on the gate control signal. For example, the gate driving circuit GD can include a scan driving unit and a light emission signal driving unit. The scan driving unit can generate a scan signal in a row-sequential manner and supply the generated scan signal to the scan lines to drive at least one or more scan lines connected to each pixel row. The light emission signal driving unit can generate a light emission signal in a row-sequential manner and supply the generated light emission signal to the light emission signal lines to drive at least one or more light emission signal lines connected to each pixel row.

According to an example embodiment, the gate driving circuit GD can be disposed in the display panel PN in a gate-driver in panel (GIP) manner. For example, the gate driving circuit GD can be divided into a plurality of pieces and disposed on at least two side surfaces of the display panel PN, respectively.

The display panel PN can include the display area and the non-display area surrounding the display area.

The display area of the display panel PN can include the plurality of pixels PX disposed in the row direction and the column direction. For example, the plurality of pixels PX can be disposed in an area where the plurality of data lines DL and the plurality of gate lines GL intersect.

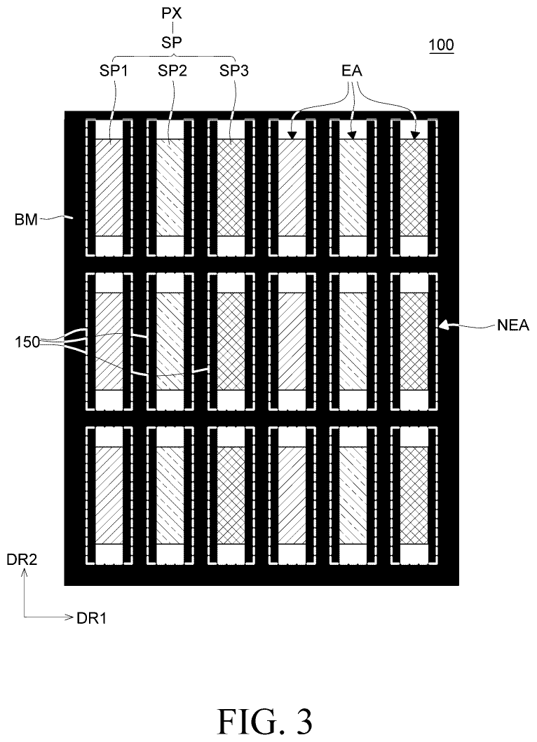

Below, the plurality of pixels PX will be described in detail with reference to FIG. 3.

FIG. 3 is a plan view of the display apparatus according to one example embodiment of the present disclosure. In FIG. 3, for convenience of illustration, the optical member 150 is drawn in a dotted line.

Referring to FIG. 3, a display apparatus 100 according to an example embodiment of the present disclosure includes a plurality of pixels PX. The plurality of pixels PX can be disposed in a matrix form along a first direction DR1 and a second direction DR2. One pixel PX can include a plurality of sub-pixels SP that emits different color light. For example, one pixel PX can include a first sub-pixel SP1, a second sub-pixel SP2, and a third sub-pixel SP3. The first sub-pixel SP1 can be a red sub-pixel, the second sub-pixel SP2 can be a green sub-pixel, and the third sub-pixel SP3 can be a blue sub-pixel. However, the present disclosure is not limited thereto, and in some cases, the pixel PX can further include a sub-pixel SP for further implementing a specific color, for example, white. In one pixel PX, a first sub-pixel SP1, a second sub-pixel SP2, and a third sub-pixel SP3 can be disposed along the first direction DR1. A light-emitting area EA of each of the plurality of sub-pixels SP can extend in the second direction DR2.

The display apparatus 100 can include the light-emitting area EA corresponding to each of the plurality of sub-pixels SP and a non-light-emitting area NEA surrounding the light-emitting area EA of each of the plurality of sub-pixels SP.

An optical member 150 that refracts light from a plurality of light-emitting elements in a specific direction can be disposed in each of the plurality of sub-pixels SP. For example, the optical members 150 can each be implemented as a lens, but the example embodiments of the present disclosure are not limited thereto.

The optical member 150 can be disposed to overlap the light-emitting area EA of each of the plurality of sub-pixels SP. Referring to FIG. 3, the optical member 150 can extend in the second direction DR2 in the same manner as the extension direction of the light-emitting area EA. For example, the planar shape of the optical member 150 can have a bar shape extending in the second direction DR2. In this case, a traveling direction of light emitted from the light-emitting area EA of the plurality of sub-pixels SP may not be limited to the second direction DR2. Meanwhile, the optical member 150 can be disposed to overlap a portion of the non-light-emitting area NEA. For example, the optical member 150 can be disposed in an area larger than the light-emitting area EA and can overlap a portion of the non-light-emitting area NEA surrounding the light-emitting area EA.

The optical member 150 can selectively provide light according to a viewing angle. For example, the optical member 150 can provide light in a first range to form a first viewing angle. In addition, the optical member 150 can provide light in a second range to form a second viewing angle. In addition, the optical member 150 can provide light in a third range to form a third viewing angle. For example, when the display panel PN is used in a vehicle described with reference to FIG. 1, the field of view of at least some areas of the display panel PN needs to be limited according to the user's request. For example, in the case of an image displayed in a display area of the display panel PN that provides entertainment functions and seat information for a passenger sitting in the passenger seat, the field of view of the image displayed in the corresponding area can need to be limited according to the user's request, since it can interfere with the driver's driving. In addition, in the case of an image displayed in a display area of the display panel PN that provides vehicle operation information for a driver sitting in the driver's seat, the image can be information that is only necessary for the driver, so the field of view of the image displayed in that area can need to be limited according to the user's request. However, the present disclosure is not limited thereto, the display panel PN can provide the image to both the driver and passengers.

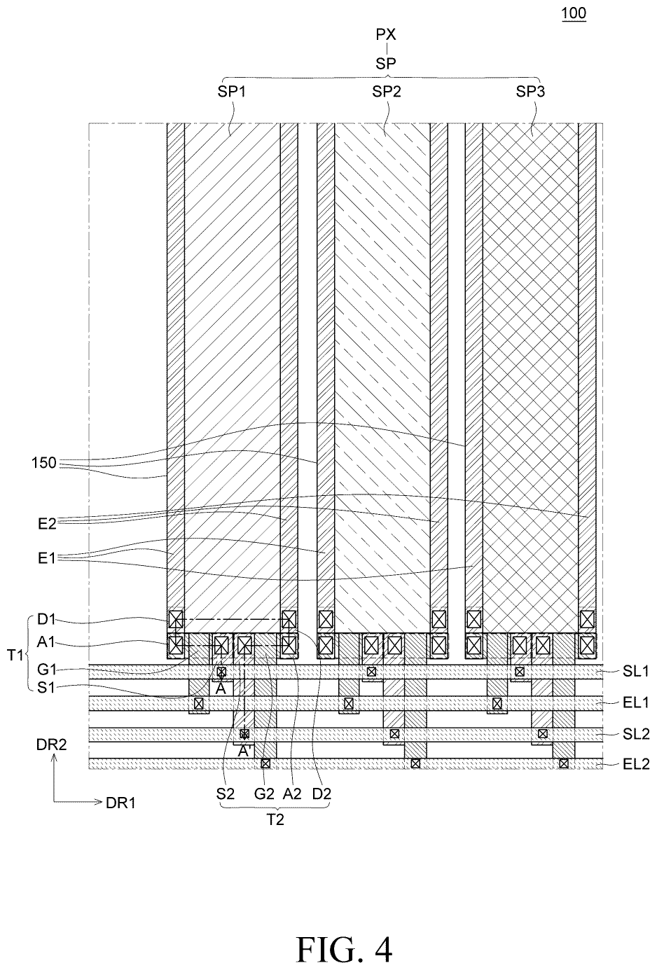

Details regarding the optical member 150 will be described later with reference to FIGS. 4 to 7.

Referring to FIG. 3, a black matrix BM is disposed to overlap the non-light-emitting area NEA. The black matrix BM can be disposed in an area excluding the light-emitting area EA to surround the light-emitting area EA.

Meanwhile, the black matrix BM can expose a portion of the non-light-emitting area NEA adjacent to the light-emitting area EA. For example, the black matrix BM can expose a portion of the non-light-emitting area NEA on both sides of the light-emitting area EA in the second direction DR2. Accordingly, light emitted from each of the plurality of sub-pixels SP that travels in the side direction can travel to the non-light-emitting area NEA exposed from the black matrix BM. Accordingly, compared to a case where the black matrix BM covers the entire non-light-emitting area NEA, the side viewing angle can be improved in the second direction DR2. For example, when the display panel PN is used in a vehicle described with reference to FIG. 1, when the first direction DR1 is the direction in which the driver's seat and the passenger seat are disposed, and the second direction DR2 is the direction in which the vehicle occupants'eye level is, the viewing angle range can be widened in the direction of the vehicle occupants'eye level. Accordingly, the content (or image) provided through the light-emitting area EA of the plurality of sub-pixels SP may not have a restricted field of view of the image depending on the height of the vehicle occupant.

The non-display area can be disposed along the perimeter of the display area. Various components for driving a pixel circuit disposed in the pixel PX can be disposed in the non-display area. For example, at least a portion of a gate driving circuit GD can be disposed in the non-display area. The non-display area can be referred to as a bezel area.

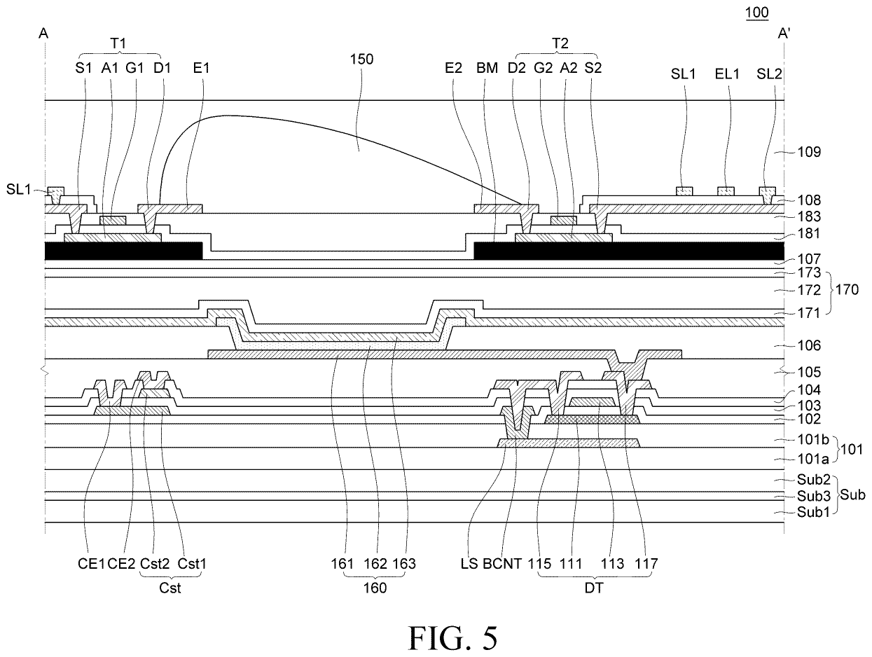

FIG. 4 is an enlarged plan view of the pixel area of the display apparatus according to one example embodiment of the present disclosure. FIG. 5 is a cross-sectional view taken along line A-A′ of FIG. 4. In FIG. 4, the illustration of a black matrix BM is omitted for convenience of illustration. FIG. 5 is a cross-sectional view of the first sub-pixel SP when both the first transistor T1 and the second transistor T2 are turned off.

Referring to FIGS. 4 and 5, in the display apparatus 100 according to one example embodiment of the present disclosure, a lower buffer layer 101, a light-shielding layer LS, a driving transistor DT, a gate insulating layer 102, an auxiliary electrode BCNT, a storage capacitor Cst, a first interlayer insulating layer 103, a second interlayer insulating layer 104, a first connection electrode CE1, a second connection electrode CE2, a first overcoating layer 105, a light-emitting element 160, a bank 106, an encapsulating layer 170, an upper buffer layer 107, a black matrix BM, a touch sensing unit, a first transistor T1, a second transistor T2, a first driving electrode E1, a second driving electrode E2, a third interlayer insulating layer 108, a first enable line EL1, a first signal line SL1, a second enable line EL2, a second signal line SL2, and a second over-coating layer 109 can be disposed above a substrate Sub.

The substrate Sub is configured to support various components included in the display apparatus 100 and can be made of an insulating material. The substrate Sub can include a first substrate Sub1, a second substrate Sub2, and an insulating layer Sub3. The insulating layer Sub3 can be disposed between the first substrate Sub1 and the second substrate Sub2. By configuring the substrate Sub with the first substrate Sub1, the second substrate Sub2, and the insulating layer Sub3 in this way, moisture penetration can be suppressed. For example, the first substrate Sub1 and the second substrate Sub2 can be polyimide PI substrates, but are not limited thereto.

The lower buffer layer 101 can be disposed on the substrate Sub. The lower buffer layer 101 can include a first lower buffer layer 101a and a second lower buffer layer 101b.

The first lower buffer layer 101a can be disposed on the substrate Sub. The first lower buffer layer 101a can reduce the penetration of moisture or impurities through the substrate Sub. The first lower buffer layer 101a can include an inorganic insulating material such as silicon oxide (SiOx) and silicon nitride (SiNx). The first lower buffer layer 101a can have a multilayer structure. For example, the first lower buffer layer 101a can have a stacked structure of a film made of silicon nitride (SiNx) and a film made of silicon oxide (SiOx).

The light-shielding layer LS can be disposed on the first lower buffer layer 101a. The light-shielding layer LS can be disposed to overlap at least a semiconductor layer 111 of the driving transistor DT to block light incident onto the semiconductor layer 111. Meanwhile, although the light-shielding layer LS is illustrated as a single layer in the drawings, the light-shielding layer LS can be formed of a plurality of layers. The light-shielding layer LS can be formed of various conductive materials, for example, magnesium (Mg), aluminum (Al), nickel (Ni), chromium (Cr), molybdenum (Mo), tungsten (W), gold (Au), or an alloy thereof.

The second lower buffer layer 101b can be disposed on the light-shielding layer LS. The second lower buffer layer 101b can protect the driving transistor DT from impurities such as alkali ions leaking from the substrate Sub. In addition, the second lower buffer layer 101b can improve adhesion between layers disposed on the second lower buffer layer 101b and the substrate Sub. In addition, the second lower buffer layer 101b can include an inorganic insulating material such as, for example, silicon oxide (SiOx) and silicon nitride (SiNx). The second lower buffer layer 101b can have a multilayer structure. For example, the second lower buffer layer 101b can have a stacked structure of a film made of silicon nitride (SiNx) and a film made of silicon oxide (SiOx).

The driving transistor DT can be disposed on the lower buffer layer 101. The driving transistor DT can include the semiconductor layer 111, a gate electrode 113, a source electrode 115, and a drain electrode 117.

The patterned semiconductor layer 111 is disposed on the lower buffer layer 101.

The semiconductor layer 111 can be made of an oxide semiconductor material. Alternatively, the semiconductor layer 111 can be made of polycrystalline silicon, in which case impurities can be doped at both edges of the semiconductor layer 111.

The gate insulating layer 102 made of an insulating material can be disposed on the semiconductor layer 111. The gate insulating layer 102 can include an insulating material. For example, the gate insulating layer 102 can include an inorganic insulating material such as silicon oxide (SiO) and silicon nitride (SiN).

The gate insulating layer 102 can extend between the semiconductor layer 111 of the driving transistor DT and the gate electrode 113.

The gate insulating layer 102 is depicted as being disposed on the entire surface of the substrate Sub, but the gate insulating layer 102 can also be patterned in the same shape as the gate electrode 113.

The gate electrode 113 made of a conductive material such as a metal is disposed corresponding to each semiconductor layer 111 on the gate insulating layer 102. In addition, a gate line can be disposed on the upper part of the gate insulating layer 102. The gate line can extend along the row direction.

The gate electrode 113 can be made of various conductive materials, such as magnesium (Mg), aluminum (Al), nickel (Ni), chromium (Cr), molybdenum (Mo), tungsten (W), gold (Au), or alloys thereof.

The auxiliary electrode BCNT is disposed on the gate insulating layer 102. The auxiliary electrode BCNT is an electrode for applying voltage to the light-shielding layer LS below the lower buffer layer 101. For example, the auxiliary electrode BCNT can be formed of the same material as the gate electrode 113 of the driving transistor DT. The auxiliary electrode BCNT can be made of various conductive materials, for example, magnesium (Mg), aluminum (Al), nickel (Ni), chromium (Cr), molybdenum (Mo), tungsten (W), gold (Au), or alloys thereof.

For example, the light-shielding layer LS can be electrically connected to another configuration disposed on the substrate Sub through the auxiliary electrode BCNT to receive voltage. For example, the auxiliary electrode BCNT can be connected to the driving transistor DT and a high-potential voltage line. Therefore, the light-shielding layer LS receiving voltage through the auxiliary electrode BCNT does not operate as a floating gate, and the threshold voltage fluctuation of the driving transistor DT caused by the floating light-shielding layer LS can be minimized or reduced.

The storage capacitor Cst including a first capacitor electrode Cst1 and a second capacitor electrode Cst2 is disposed on the gate insulating layer 102.

The first capacitor electrode Cst1 of the storage capacitor Cst can be disposed on the gate insulating layer 102. For example, the first capacitor electrode Cst1 can be formed of the same material as the gate electrode 113 of the driving transistor DT. The first capacitor electrode Cst1 can be made of various conductive materials, for example, magnesium (Mg), aluminum (Al), nickel (Ni), chromium (Cr), molybdenum (Mo), tungsten (W), gold (Au), or alloys thereof.

The first interlayer insulating layer 103 can be disposed on the gate electrode 113 and the first capacitor electrode Cst1. The first interlayer insulating layer 103 can include a contact hole for exposing the semiconductor layer 111 of the driving transistor DT, a contact hole for exposing the first capacitor electrode Cst1, and a contact hole for exposing the auxiliary electrode BCNT. The first interlayer insulating layer 103 can include an insulating material. For example, the first interlayer insulating layer 103 can include an inorganic insulating material such as silicon oxide (SiO) and silicon nitride (SiN).

The first interlayer insulating layer 103 can be positioned on the gate insulating layer 102. The first interlayer insulating layer 103 can extend between the gate electrode 113 and the source electrode 115 of the driving transistor DT and between the gate electrode 113 and the drain electrode 117. For example, the source electrode 115 and the drain electrode 117 of the driving transistor DT can be insulated from the gate electrode 113 by the first interlayer insulating layer 103. The first interlayer insulating layer 103 can cover the gate electrode 113 of the driving transistor DT.

The second capacitor electrode Cst2 of the storage capacitor Cst can be disposed on the first interlayer insulating layer 103. The second capacitor electrode Cst2 can be disposed on the first interlayer insulating layer 103 so as to overlap the first capacitor electrode Cst1.

The second capacitor electrode Cst2 can be made of various conductive materials, such as magnesium (Mg), aluminum (Al), nickel (Ni), chromium (Cr), molybdenum (Mo), tungsten (W), gold (Au), or alloys thereof.

The second interlayer insulating layer 104 can be disposed on the first interlayer insulating layer 103. The second interlayer insulating layer 104 can include a contact hole for exposing the semiconductor layer 111 of the driving transistor DT, a contact hole for exposing the first capacitor electrode Cst1 and the second capacitor electrode Cst2, and a contact hole for exposing the auxiliary electrode BCNT. The second interlayer insulating layer 104 can be composed of a single layer of silicon nitride (SiNx) or silicon oxide (SiOx) or a multilayer thereof, but is not limited thereto.

The source electrode 115 and the drain electrode 117 can be positioned on the second interlayer insulating layer 104. The source electrode 115 and the drain electrode 117 can be made of various conductive materials, for example, magnesium (Mg), aluminum (Al), nickel (Ni), chromium (Cr), molybdenum (Mo), tungsten (W), gold (Au), or alloys thereof.

The source electrode 115 and the drain electrode 117 is in contact with the semiconductor layer 111 through contact holes in the second interlayer insulating layer 104, the first interlayer insulating layer 103, and the gate insulating layer 102.

The drain electrode 117 of the driving transistor DT can be electrically connected to an anode electrode 161 of the light-emitting element 160 to be described later.

The first connection electrode CE1 can be positioned on the second interlayer insulating layer 104. The first connection electrode CE1 can be electrically connected to the first capacitor electrode Cst1 through the contact holes of the second interlayer insulating layer 104 and the first interlayer insulating layer 103. For example, the first connection electrode CE1 can be electrically connected to another component disposed on the substrate Sub and can apply a voltage to the first capacitor electrode Cst1. The first connection electrode CE1 can be made of various conductive materials, for example, magnesium (Mg), aluminum (Al), nickel (Ni), chromium (Cr), molybdenum (Mo), tungsten (W), gold (Au), or alloys thereof.

The second connection electrode CE2 can be positioned on the second interlayer insulating layer 104. The second connection electrode CE2 can be electrically connected to the second capacitor electrode Cst2 through the contact hole of the second interlayer insulating layer 104. In addition, the first connection electrode CE1 can be electrically connected to another component disposed on the substrate Sub and can apply a voltage to the first capacitor electrode Cst1. For example, the second connection electrode CE2 can be electrically connected to the source electrode 115 or the drain electrode 117, but is not limited thereto. The second connection electrode CE2 can be made of various conductive materials, for example, magnesium (Mg), aluminum (Al), nickel (Ni), chromium (Cr), molybdenum (Mo), tungsten (W), gold (Au), or alloys thereof.

The first overcoating layer 105 can be disposed on the driving transistor DT, the first connection electrode CE1, and the second connection electrode CE2. The first overcoating layer 105 can include an insulating material. The first overcoating layer 105 can include an organic insulating material. For example, the first overcoating layer 105 can be made of, but is not limited to, polyimide, acrylic, or a benzocyclobutene (BCB)-based resin.

The light-emitting element 160 can be positioned on the first overcoating layer 105. The light-emitting element 160 can include the anode electrode 161, a light-emitting structure 162, and a cathode electrode 163 sequentially stacked on the substrate Sub.

The anode electrode 161 can include a conductive material. The anode electrode 161 can include a material having high reflectivity. For example, the anode electrode 161 can include a metal such as aluminum Al and silver Ag. The anode electrode 161 can have a multilayer structure. For example, the anode electrode 161 can have a structure in which a reflective electrode made of a metal is positioned between transparent electrodes made of a transparent conductive material such as indium tin oxide (ITO), indium zinc oxide (IZO), or the like.

The anode electrode 161 of the light-emitting element 160 can be electrically connected to the drain electrode 117 (or source electrode 115) of the driving transistor DT through the contact hole of the first overcoating layer 105.

The bank 106 can be positioned between the anode electrodes 161. The bank 106 can include an insulating material. For example, the bank 106 can include an organic insulating material. For example, the bank 106 can be made of a polyimide, an acrylic, or a benzocyclobutene (BCB)-based resin, and the bank 106 can include a material different from the first overcoating layer 105.

The bank 106 can cover a portion of the anode electrode 161 of the light-emitting element 160. For example, the bank 106 can cover an edge of the anode electrode 161. The bank 106 can define a light-emitting area EA. For example, the light-emitting area EA can be defined as an area of the anode electrode 161 exposed by the bank 106.

The light-emitting structure 162 is disposed on the first electrode 151. The light-emitting structure 162 can include a light-emitting layer that emits light of a specific color. For example, the light-emitting structure 162 disposed in the first sub-pixel SP1 can be different from the light-emitting structure 162 disposed in the second sub-pixel SP2 and the light-emitting structure 162 disposed in the third sub-pixel SP3. Meanwhile, the light-emitting structure 162 can include at least one of a light-emitting layer, a hole injection layer HIL, a hole transport layer HTL, an electron transport layer ETL, and an electron injection layer EIL. However, the present disclosure is not limited thereto, and the light-emitting structure 162 can further include a common layer that is commonly disposed in the first sub-pixel SP1, the second sub-pixel SP2, and the third sub-pixel SP3.

The cathode electrode 163 is disposed on the light-emitting structure 162. The cathode electrode 163 can include a conductive material. The transmittance of the cathode electrode 163 can be higher than the transmittance of the anode electrode 161. For example, the cathode electrode 163 can be made of a transparent conductive material such as indium tin oxide (ITO), indium zinc oxide (IZO), or the like. Accordingly, in the display apparatus 100 according to the example embodiment of the present disclosure, light generated by the light-emitting structure 162 can be emitted through the cathode electrode 163.

The encapsulating layer 170 can be positioned on the light-emitting element 160. The encapsulating layer 170 can suppress damage to the light-emitting element 160 due to moisture and impact from the outside.

The encapsulating layer 170 can have a multilayer structure. For example, the encapsulating layer 170 can include a first encapsulating layer 171, a second encapsulating layer 172, and a third encapsulating layer 173 that are sequentially stacked, but the example embodiments of the present disclosure are not limited thereto.

The first encapsulating layer 171 can be disposed on the light-emitting element 160 to suppress the penetration of moisture or oxygen. The first encapsulating layer 171 can be made of an inorganic material such as silicon oxide (SiOx), silicon nitride (SiNx), silicon oxynitride (SiNxOy), or aluminum oxide (AlyOz), but is not limited thereto.

The second encapsulating layer 172 is disposed on the first encapsulating layer 171 to flatten the surface. In addition, the second encapsulating layer 172 can cover foreign materials or particles that can occur during the manufacturing process. The second encapsulating layer 172 can be made of an organic material, for example, silicon oxycarbon (SiOxCz), acrylic or epoxy resin, but is not limited thereto.

The third encapsulating layer 173 can be disposed on the second encapsulating layer 172 and suppress the penetration of moisture or oxygen like the first encapsulating layer 171. In this case, the third encapsulating layer 173 and the first encapsulating layer 171 can be formed to seal the second encapsulating layer 172. Therefore, the penetration of moisture or oxygen into the light-emitting element 160 can be reduced more effectively by the third encapsulating layer 173. The third encapsulating layer 173 can be made of an inorganic material such as silicon oxide (SiOx), silicon nitride (SiNx), silicon oxynitride (SiNxOy), or aluminum oxide (AlyOz), but is not limited thereto.

The upper buffer layer 107 can be disposed on the encapsulating layer 170. The upper buffer layer 107 can reduce the inflow of impurities such as alkali ions, and can improve the adhesion between the touch sensing unit disposed above the upper buffer layer 107 and the encapsulating layer 170 below the upper buffer layer 107. The upper buffer layer 107 can include, for example, an inorganic insulating material such as silicon oxide (SiOx) and silicon nitride (SiNx). In addition, the upper buffer layer 107 can have a stacked structure made of, for example, a film made of silicon nitride (SiNx) and silicon oxide (SiOx), but is not limited thereto.

The black matrix BM can be disposed on the upper buffer layer 107.

The black matrix BM can be disposed to reduce color mixing between the plurality of sub-pixels SP. Accordingly, the black matrix BM can be disposed to overlap the bank 106 disposed in the non-light-emitting area NEA.

The touch sensing unit, the first transistor T1, the second transistor T2, the first driving electrode E1, and the second driving electrode E2 can be disposed on the upper buffer layer 107 and the black matrix BM.

Referring to FIG. 5, the first transistor T1 and the second transistor T2 can be disposed on the upper buffer layer 107 and the black matrix BM. Each of the first transistor T1 and the second transistor T2 can be disposed in each of the plurality of sub-pixels SP. For example, the first transistor T1 and the second transistor T2 can be disposed on both sides of each of the plurality of sub-pixels SP. Referring to FIG. 4, in one sub-pixel SP, the first transistor T1 and the second transistor T2 can be disposed sequentially along the first direction DR1.

Referring to FIG. 4 together with FIG. 5, a first gate electrode G1 of the first transistor T1 can be connected to the first enable line EL1 providing a first selection signal. When the plurality of sub-pixels SP is driven in a first driving mode, the first selection signal can be supplied to the first gate electrode G1 of the first transistor T1 to turn on the first transistor T1. Accordingly, a current path of a first driving current can be formed in the first driving electrode E1 in contact with the plurality of optical members 150. The first driving current applied to the first driving electrode E1 can provide light of the plurality of sub-pixels SP in the first range to form the first viewing angle.

Here, the first driving mode can be determined by a user's input or when a pre-specified condition is satisfied. In addition, the first driving mode can be determined by a sensor disposed within the display apparatus 100. For example, the eye positions of the driver and/or passenger can be recognized through a camera disposed within the display apparatus 100, and the first viewing angle can be formed in which light of the plurality of sub-pixels SP is provided according to the eye positions of the driver and/or passenger. For example, a first area among the display areas of the display panel PN can be driven in the first driving mode to provide an image of the display panel PN only to the driver.

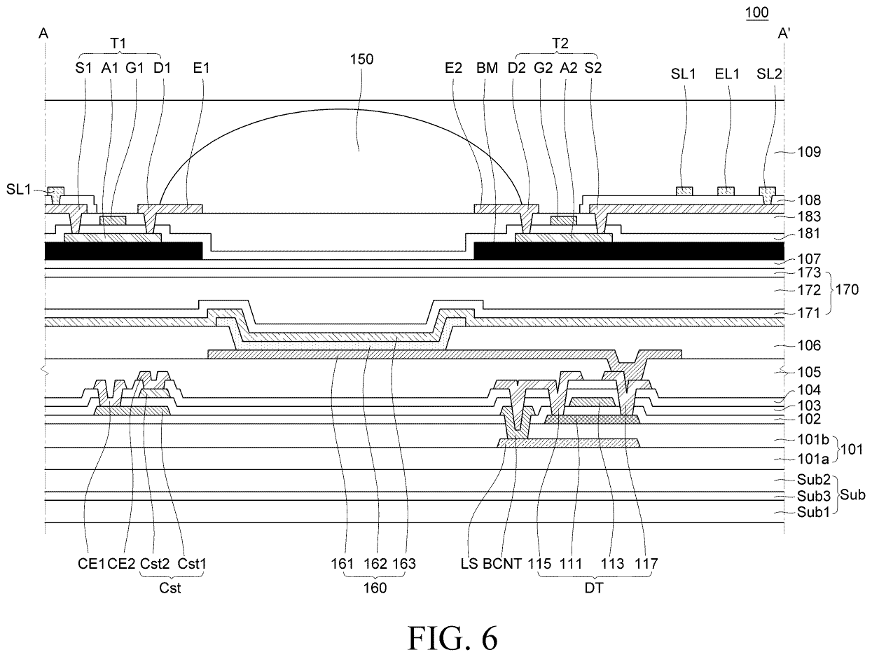

The first driving mode of the plurality of sub-pixels SP according to the first transistor T1 will be described later with reference to FIG. 6.

A second gate electrode G2 of the second transistor T2 can be connected to a second enable line EL2 providing a second selection signal. When the plurality of sub-pixels SP is driven in the second driving mode, the second selection signal can be supplied to the gate electrode G2 of the second transistor T2 to turn on the second transistor T2. Accordingly, a current path of a second driving current can be formed in the second driving electrode E2 in contact with the plurality of optical members 150. The second driving current applied to the second driving electrode E2 can provide light of the plurality of sub-pixels SP in a second range to form a second viewing angle.

Here, the second driving mode can be determined by a user's input or when a pre-specified condition is satisfied. In addition, the second driving mode can be determined by a sensor disposed within the display apparatus 100. For example, the eye positions of the driver and/or passenger can be recognized through a camera disposed within the display apparatus 100, and the second viewing angle can be formed in which light of the plurality of sub-pixels SP is provided according to the eye positions of the driver and/or passenger. For example, a second area among the display areas of the display panel PN can be driven in the second driving mode to provide the image of the display panel PN only to the passenger.

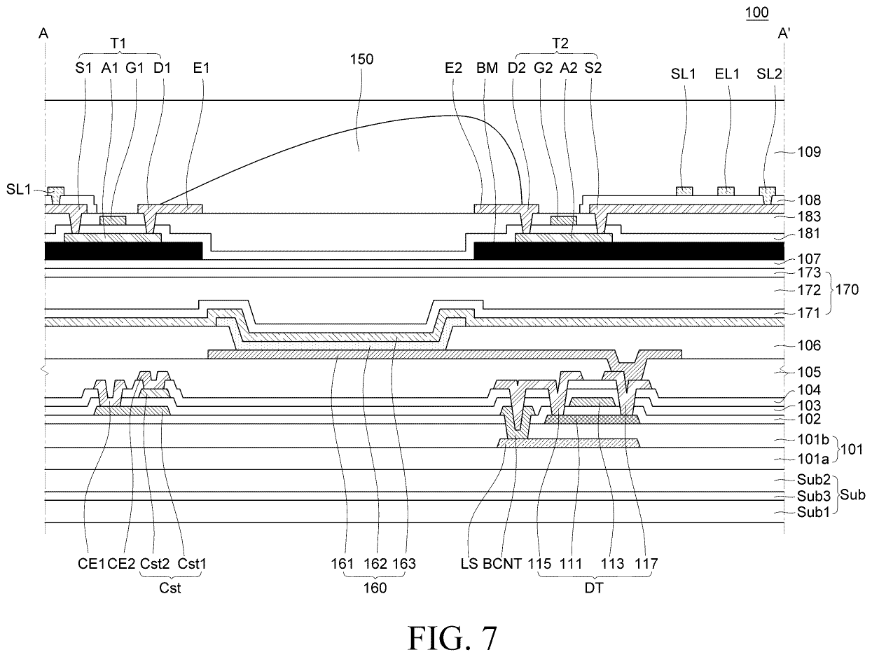

The second driving mode of the plurality of sub-pixels SP according to the second transistor T2 will be described later with reference to FIG. 7.

First, the first transistor T1 can include a first semiconductor layer A1, a first gate electrode G1, a first source electrode S1, and a first drain electrode D1. Referring to FIG. 5, the first semiconductor layer A1 of the first transistor T1 can be disposed on a black matrix BM.

The first semiconductor layer A1 can be disposed to overlap the black matrix BM. Accordingly, light incident from the black matrix BM to the first semiconductor layer A1 can be blocked.

A first touch insulating layer 181 can be disposed on the first semiconductor layer A1. The first touch insulating layer 181 can extend between the first semiconductor layer A1 and the first gate electrode G1 to insulate the first semiconductor layer A1 and the first gate electrode G1. In addition, the first touch insulating layer 181 can cover the top surface and the side surface of the black matrix BM. The first touch insulating layer 181 can be made of an inorganic material. For example, the first touch insulating layer 181 can be made of an inorganic material such as silicon nitride (SiNx), silicon oxide nitride (SiON), or the like, but is not limited thereto.

The first gate electrode G1 can be disposed on the first touch insulating layer 181. The first gate electrode G1 can be disposed on the same layer as a bridge electrode. Referring to FIG. 4, the first gate electrode G1 can extend in the second direction DR2 and be connected to the first enable line EL1 extending in the first direction DR1.

A second touch insulating layer 183 can be disposed on the first gate electrode G1. The second touch insulating layer 183 can extend between the first gate electrode G1 and the first source electrode S1 and between the first gate electrode G1 and the first drain electrode D1 to insulate the first gate electrode G1 and the first source electrode S1 and the first gate electrode G1 and the first drain electrode D1. The second touch insulating layer 183 can be made of an organic insulating material or an inorganic insulating material. For example, the second touch insulating layer 183 can be made of an organic material such as photo acryl, a benzocyclobutene (BCB), polyimide (PI), or polyamide (PA), or can be made of an inorganic material such as silicon nitride (SiNx), silicon oxide nitride (SiON), or the like, but is not limited thereto.

Meanwhile, the second touch insulating layer 183 can include a contact hole for exposing the first gate electrode G1 of the first transistor T1 and a contact hole for exposing the second gate electrode G2 of the second transistor T2.

The first source electrode S1 and the first drain electrode D1 can be disposed on the second touch insulating layer 183. The first source electrode S1 and the first drain electrode D1 can be disposed on the same layer as the touch electrode.

The first source electrode S1 can extend in the second direction DR2 and be connected to the first signal line SL1 extending in the first direction DR1. The first drain electrode D1 can extend in the second direction DR2 and be connected to the first driving electrode E1 extending in the first direction DR1.

The first driving electrode E1 can be disposed on the second touch insulating layer 183. The first driving electrode E1 can be connected to the first drain electrode D1 and can receive the first selection signal applied to the first drain electrode D1. For example, the first driving electrode E1 can be formed integrally with the first drain electrode D1 and can be disposed on the same layer as the first drain electrode D1. In addition, the first driving electrode E1 can be disposed on the same layer as the touch electrode.

The first driving electrode E1 can extend in the second direction DR2. The first driving electrode E1 can be disposed along the extension direction of the optical member 150 and the extension direction of each of the plurality of sub-pixels SP.

The first driving electrode E1 can be disposed on one side of the plurality of light-emitting elements 160. In this case, the first driving electrode E1 can be disposed to overlap one side of the optical member 150. For example, the first driving electrode E1 can be in contact with one side of the optical member 150 extending in the second direction DR2.

The second transistor T2 can include the second semiconductor layer A2, the second gate electrode G2, a second source electrode S2, and a second drain electrode D2. The first transistor T1 can have the same or similar structure as the second transistor T2.

For example, the second semiconductor layer A2 can be disposed on the black matrix BM to overlap the black matrix BM. The first touch insulating layer 181 can be disposed on the second semiconductor layer A2, and the second gate electrode G2 can be disposed on the first touch insulating layer 181. Referring to FIG. 4, the second gate electrode G2 can extend in the second direction DR2 and be connected to the second enable line EL2 extending in the first direction DR1. The second touch insulating layer 183 can be disposed on the second gate electrode G2. The second source electrode S2 and the second drain electrode D2 can be disposed on the second touch insulating layer 183. Referring to FIG. 4, the second source electrode S2 can extend in the second direction DR2 and be connected to the second signal line SL2 extending in the first direction DR1. The second drain electrode D2 can extend in the second direction DR2 and be connected to the second driving electrode E2 extending in the first direction DR1.

The second driving electrode E2 can be disposed on the second touch insulating layer 183. The second driving electrode E2 can be connected to the second drain electrode D2 and can receive the second selection signal applied to the second drain electrode D2. For example, the second driving electrode E2 can be formed integrally with the second drain electrode D2 and can be disposed on the same layer as the second drain electrode D2. In addition, the second driving electrode E2 can be disposed on the same layer as the touch electrode.

The second driving electrode E2 can extend in the second direction DR2. The second driving electrode E2 can be disposed along the extension direction of the optical member 150 and the extension direction of each of the plurality of sub-pixels SP.

The second driving electrode E2 can be disposed on the other side of the plurality of light-emitting elements 160. For example, the second driving electrode E2 can be disposed along the first direction DR1 to be spaced apart from the first driving electrode E1 while interposing the light-emitting elements 160 of the plurality of sub-pixels SP therebetween. In addition, the second driving electrode E2 can be disposed to overlap the other side of the optical member 150. For example, the second driving electrode E2 can also be in contact with the other side of the optical member 150 extending in the second direction DR2.

Meanwhile, the display apparatus 100 can include the touch sensing unit including the bridge electrode and the touch electrode. The touch sensing unit can be disposed in the display area including the light-emitting element 160 to sense a touch input. For example, the bridge electrode can be disposed on a first touch insulating layer, and the touch electrode can be disposed on a second touch insulating layer. The bridge electrode can be configured to connect a touch electrode that is disconnected at a point where the touch electrode extending in the row direction and the touch electrode extending in a column direction intersect each other. The touch electrodes can be configured to be disposed in the row direction and the column direction to sense an external touch input using a user's finger or a touch pen, or the like.

The display apparatus 100 can include a routing line that extends the touch electrode disposed at the outermost edge of the display area to a touch pad disposed in a non-display area.

The optical member 150 is disposed on the first driving electrode E1, the second driving electrode E2, and the second touch insulating layer 183. The optical member 150 can have a shape in which light in at least one direction may not be restricted. For example, the shape of the optical member 150 positioned within a plurality of sub-pixels SP can be a semi-cylindrical shape extending in the second direction DR2.

The optical member 150 can cover the top surface of the second touch insulating layer 183 disposed in the light-emitting area EA, and can cover a portion of the top surface of the first driving electrode E1 and a portion of the top surface of the second driving electrode E2 disposed in the non-light-emitting area NEA.

The optical member 150 can be made of a material including polar molecules. For example, the optical member 150 can include polar molecules dispersed in a fluid. For example, the optical member 150 can include a polymer-stabilized liquid crystal (PSLC), but is not limited thereto.

When both the first transistor T1 and the second transistor T2 are turned off, the first driving electrode E1 and the second driving electrode E2 can be in a floating state. Accordingly, the polar molecules constituting the optical member 150 can maintain an evenly distributed state. Accordingly, the optical member 150 can maintain a symmetrical shape with respect to the central axis.

The polar molecules included in the optical member 150 can move according to an electric field formed in the optical member 150. For example, the optical member 150 can include a dipole material that shifts in a direction in which a high voltage is applied. Accordingly, when an electric field is formed between the first driving electrode E1 and the second driving electrode E2, the optical member 150 can shift toward the first driving electrode E1 side or the second driving electrode E2 side. Accordingly, when the first driving electrode E1 and the second driving electrode E2 are sequentially disposed along the first direction DR1, light emitted from the light-emitting element 160 that is incident on the optical member 150 side can be refracted in the first direction DR1 and can travel in the side direction. Accordingly, the optical member 150 can limit the viewing angle range of the light-emitting element 160 in the first direction DR1 or improve the side viewing angle.

The driving mode of the sub-pixel SP is described in detail later with reference to FIGS. 6 and 7.

The third interlayer insulating layer 108 can be disposed on the first transistor T1 and the second transistor T2. The third interlayer insulating layer 108 can be disposed in an area that does not overlap with the optical member 150, the first driving electrode E1, and the second driving electrode E2. For example, as illustrated in FIG. 5, the third interlayer insulating layer 108 can expose the top surfaces of the first driving electrode E1 and the second driving electrode E2, and can expose the top surface of the second touch insulating layer 183 in the light-emitting area EA.

The third interlayer insulating layer 108 can cover the top surfaces of the first source electrode S1 of the first transistor T1 and the second source electrode S2 of the second transistor T2. The third interlayer insulating layer 108 can extend between the second source electrode S2, the first signal line SL1, and the first enable line EL1, thereby insulating between the second source electrode S2, the first signal line SL1, and the first enable line EL1.

The third interlayer insulating layer 108 can include a contact hole for exposing the first source electrode S1 of the first transistor T1 and the second source electrode S2 of the second transistor T2. In addition, the third interlayer insulating layer 108 can include a contact hole for exposing the first gate electrode G1 of the first transistor T1 and a contact hole for exposing the second gate electrode G2 of the second transistor T2.

The first enable line EL1, the first signal line SL1, the second enable line EL2, and the second signal line SL2 can be disposed on the third interlayer insulating layer 108. Each of the first enable line EL1, the first signal line SL1, the second enable line EL2, and the second signal line SL2 can extend in the same direction. For example, each of the first enable line EL1, the first signal line SL1, the second enable line EL2, and the second signal line SL2 can extend in the first direction DR1. Although FIG. 4 illustrates that the first signal line SL1, the first enable line EL1, the second signal line SL2, and the second enable line EL2 are sequentially disposed along the second direction DR2, the order of the first signal line SL1, the first enable line EL1, the second signal line SL2, and the second enable line EL2 is not limited thereto.

A signal identical to a power signal applied to a plurality of sub-pixels SP can be supplied to the first signal line SL1. For example, a high-potential power voltage can be applied to the first signal line SL1, but is not limited thereto. The first signal line SL1 can be electrically connected to the first source electrode S1 of the first transistor T1 through the contact hole of the third interlayer insulating layer 108. The first signal line SL1 can extend in the first direction DR1 and can be electrically connected to the first source electrodes S1 of the plurality of first transistors T1 disposed in the first direction DR1.

The first selection signal for turning on the first transistor T1 can be applied to the first enable line EL1. Accordingly, the first transistor T1 can transmit the high-potential power voltage to the first driving electrode E1 in response to the first selection signal. The first enable line EL1 can be electrically connected to a first gate electrode G1 of the first transistor T1 through the contact hole of the third interlayer insulating layer 108 and the second touch insulating layer 183. The first enable line EL1 can extend in the first direction DR1 and can be electrically connected to the first gate electrodes G1 of the plurality of first transistors T1 disposed in the first direction DR1.

The signal identical to the power signal applied to the plurality of sub-pixels SP can be supplied to the second signal line SL2. For example, a high-potential power voltage can be applied to the second signal line SL2, but is not limited thereto. The second signal line SL2 can be electrically connected to the second source electrode S2 of the second transistor T2 through the contact hole of the third interlayer insulating layer 108. The second signal line SL2 can extend in the first direction DR1 and can be electrically connected to the second source electrodes S2 of the plurality of second transistors T2 disposed in the first direction DR1.

The second selection signal for turning on the second transistor T2 can be applied to a second enable line EL2. Accordingly, the second transistor T2 can transmit the high-potential power voltage to the second driving electrode E2 in response to the second selection signal. The second enable line EL2 can be electrically connected to the second gate electrode G2 of the second transistor T2 through the contact hole of the third interlayer insulating layer 108 and the second touch insulating layer 183. The second enable line EL2 can extend in the first direction DR1 and can be electrically connected to the second gate electrodes G2 of the plurality of second transistors T2 disposed in the first direction DR1.

The second over-coating layer 109 can be disposed on the first enable line EL1, the first signal line SL1, the second enable line EL2, the second signal line SL2, and the optical member 150. The second over-coating layer 109 can cover the top surfaces and side surfaces of the first enable line EL1, the first signal line SL1, the second enable line EL2, the second signal line SL2, and the optical member 150, and can flatten the upper portions of the first enable line EL1, the first signal line SL1, the second enable line EL2, the second signal line SL2, and the optical member 150. In addition, the shape of the second over-coating layer 109 can vary to respond to shape deformation of the optical member 150. The second over-coating layer 109 can be made of an organic material. For example, the second over-coating layer 109 can be made of, but is not limited to, photo acryl, benzocyclobutene BCB, polyimide PI, or polyamide PA.

Below, the driving mode of the sub-pixel SP is described in detail later with reference to FIGS. 6 and 7.

FIG. 6 is a cross-sectional view illustrating the display apparatus according to the first driving mode of the present disclosure. Particularly, FIG. 6 is a cross-sectional view of the sub-pixel SP when the first transistor T1 is turned on and the second transistor T2 is turned off.

Referring to FIG. 6, when the first transistor T1 is turned on, the first driving current can be applied to the first driving electrode E1 extended from the first transistor T1, and when the second transistor T2 is turned off, the driving current may not be transmitted to the second driving electrode E2 extended from the second transistor T2. Accordingly, the second driving electrode E2 can be floated. Meanwhile, when a signal identical to a high-potential power voltage is applied from the first transistor T1 to the first driving electrode E1, an electric field can be formed between the first driving electrode E1 and the second driving electrode E2.

The polar molecules constituting the optical member 150 can move toward the first driving electrode E1 side to which the high-potential power voltage is applied. Therefore, as illustrated in FIG. 6, the optical member 150 can shift toward the first driving electrode E1 side. Accordingly, light emitted from the light-emitting element 160, which is incident toward the optical member 150, can be refracted toward the first driving electrode E1 side and travel in the side direction. Accordingly, the brightness of the image displayed from each sub-pixel SP on the first driving electrode E1 side, that is, the brightness on the first driving electrode E1 side of the display apparatus 100, can increase. Meanwhile, the brightness on the second driving electrode E2 side, that is, the brightness on the second driving electrode E2 side of the display apparatus 100 can decrease. Accordingly, the viewing angle range on the first driving electrode E1 side can be widened, and the viewing angle range on the second driving electrode E2 side can be limited.

FIG. 7 is a cross-sectional view illustrating the display apparatus according to the second driving mode of the present disclosure. Particularly, FIG. 7 is a cross-sectional view of the sub-pixel SP when the second transistor T2 is turned on and the first transistor T1 is turned off.

Referring to FIG. 7, when the second transistor T2 is turned on, the second driving current can be applied to a second driving electrode E2 extended from the second transistor T2, and when the second transistor T2 is turned off, the driving current may not be transmitted to the first driving electrode E1 extended from the second transistor T2. Accordingly, the first driving electrode E1 can be floated. Meanwhile, when the signal identical to the high-potential power voltage is applied from the second transistor T2 to the second driving electrode E2, an electric field can be formed between the first driving electrode E1 and the second driving electrode E2.

The polar molecules constituting the optical member 150 can move toward the second driving electrode E2 side to which the high-potential power voltage is applied. Therefore, as illustrated in FIG. 7, the optical member 150 can shift toward the second driving electrode E2 side. Accordingly, light emitted from the light-emitting element 160, which is incident toward the optical member 150, can be refracted toward the second driving electrode E2 side and travel in the side direction. Accordingly, the brightness of the image displayed from each sub-pixel SP on the second driving electrode E2 side, that is, the brightness on the second driving electrode E2 side of the display apparatus 100, can increase. The brightness on the first driving electrode E1 side, that is, the brightness on the first driving electrode E1 side of the display apparatus 100, can decrease. Accordingly, the viewing angle range on the second driving electrode E2 side can be widened, and the viewing angle range on the first driving electrode E1 side can be limited.

The plurality of sub-pixels SP can be driven in a third driving mode. The third driving mode can be determined by a user's input or when a pre-specified condition is satisfied. In addition, the third driving mode can be determined by a sensor disposed within the display apparatus 100. For example, the eye positions of the driver and/or passenger can be recognized through a camera disposed within the display apparatus 100, and a third viewing angle can be formed in which light of the plurality of sub-pixels SP is provided according to the eye positions of the driver and/or passenger. In this case, only a portion of the display area of the display panel PN can be driven in the third driving mode. For example, only one of the first area and the second area of the display panel PN can be driven in the third mode. However, the present disclosure is not limited thereto, and all areas of the display area of the display panel PN can be driven in the third mode.

When the plurality of sub-pixels SP is driven in the third driving mode, both the first transistor T1 and the second transistor T2 can be turned off. For example, in the third driving mode, the optical members 150 of each of the plurality of sub-pixels SP can maintain a symmetrical shape with respect to the central axis, like the optical member 150 of the first sub-pixel SP1 described with reference to FIG. 5. Accordingly, among the light emitted from the light-emitting element 160, light incident on the optical member 150 side is refracted in the front direction, and the frontal brightness of the image displayed from each sub-pixel SP can increase.

The display apparatus of a vehicle needs to appropriately display content so as not to interfere with the operation of the vehicle. For example, the display apparatus can need to limit the field of view of an image depending on a user request and/or content. Accordingly, the shape of the optical member disposed in the display apparatus is controlled to limit the range of the viewing angle of the image. However, since the view angle range is limited depending on the shape of the optical member, pixels corresponding to the view angle are separately required in order to limit the viewing angle. For example, a plurality of pixels, a plurality of pixel circuits, and a plurality of optical members that form a certain range of the viewing angle is typically separately added to the display apparatus. In this case, there is a problem in that the process cost and the manufacturing cost increase, and a problem in that the pitch and resolution of the pixels deteriorate can occur.

Accordingly, in the display apparatus 100 according to one example embodiment of the present disclosure, the shape of the optical member 150 is not fixed, and the shape of the optical member 150 can vary depending on the potential difference between the first driving electrode E1 and the second driving electrode E2. Accordingly, the shape of the optical member 150 can vary, so that the viewing angle of light emitted from the plurality of sub-pixels SP can vary. For example, the optical member 150 can move toward the first driving electrode E1 side or the second driving electrode E2 side depending on the potential difference between the first driving electrode E1 and the second driving electrode E2, and accordingly, the optical axis of the optical member 150 can move toward the first driving electrode E1 or the second driving electrode E2 side. Accordingly, the viewing angle control of the image displayed from the light-emitting element 160 can be more effectively performed based on the signal applied to the first driving electrode E1 and the second driving electrode E2. Therefore, when the display apparatus 100 is used in a vehicle, the viewing angle can be controlled more effectively by adjusting the relative brightness for the driver and passengers.

Accordingly, the display apparatus 100 according to one example embodiment of the present disclosure can adjust the viewing angle according to the variable shape of the optical member 150, and thus can selectively provide an image of the display apparatus 100 according to the viewing angle of the viewer. For example, when the display apparatus 100 is used in a vehicle, the eye positions of the driver and/or passenger can be recognized through a camera located within the display apparatus 100. Accordingly, the shape of the optical member 150 can be selectively changed by applying the electrical signal to the first driving electrode E1 and the second driving electrode E2 according to the eye positions of the driver and/or passenger. For example, according to the eye positions of the driver and/or passenger, the first area among the display areas of the display panel PN can provide light in the first range to form the first viewing angle, while the second area can provide light in the second range to form a second viewing angle. Accordingly, light from a plurality of sub-pixels SP can be selectively provided to the driver and passengers, and different images can be provided to the driver and passengers respectively.

In addition, the display apparatus 100 according to one example embodiment of the present disclosure can adjust the viewing angle according to the variable shape of the optical member 150. Therefore, separate pixels, pixel circuits, and optical members for the viewing angle adjustment are not required, so that process costs and manufacturing costs can be reduced, and problems of reduced pitch and resolution of pixels PX in a limited area can be suppressed. Accordingly, the driving voltage of the display apparatus 100 can be lowered, so that power consumption can be reduced, and since brightness and heat generation are reduced, the lifespan of the display apparatus 100 can be improved.

The example embodiments of the present disclosure can also be described as follows:

According to an aspect of the present disclosure, there is provided a display apparatus. The display apparatus comprises a substrate having a plurality of sub-pixels defined, a plurality of light-emitting elements disposed in each of the plurality of sub-pixels, an encapsulating layer disposed on the plurality of light-emitting elements, a plurality of optical members disposed on the encapsulating layer for each of the plurality of sub-pixels, a plurality of first transistors disposed on the encapsulating layer, a plurality of second transistors disposed on the encapsulating layer, a plurality of first driving electrodes connected to the plurality of first transistors on the encapsulating layer and in contact with one side of the plurality of optical members; and a plurality of second driving electrodes connected to the plurality of second transistors on the encapsulating layer and in contact with the other side of the plurality of optical members.

The plurality of first driving electrodes and the plurality of second driving electrodes can be disposed to be spaced apart from each other along a first direction with the plurality of light-emitting elements therebetween.

The plurality of optical members can be in a shape of bars extending in a second direction.

In the plurality of first driving electrodes and the plurality of second driving electrodes, the plurality of optical members can be shifted in a direction of a driving electrode in which a high potential voltage is applied.

The plurality of optical members can be symmetrical with respect to a central axis when the plurality of first transistors and the plurality of second transistors is turned off.

The display apparatus can further comprise a bridge electrode disposed on the encapsulating layer and a touch electrode disposed on the bridge electrode, wherein the plurality of first driving electrodes and the plurality of second driving electrodes can be disposed on a same layer as the touch electrode.

The display apparatus can further comprise a black matrix disposed between the encapsulating layer and the plurality of first transistors and the plurality of second transistors.

The display apparatus can further comprise an insulating layer disposed on the plurality of first transistors and the plurality of second transistors, a plurality of first signal lines disposed on the insulating layer and connected to the plurality of first transistors, a plurality of first enable lines disposed on the insulating layer and connected to the plurality of first transistors, a plurality of second signal lines disposed on the insulating layer and connected to the plurality of second transistors, and a plurality of second enable lines disposed on the insulating layer and connected to the plurality of second transistors.

The plurality of optical members can include a dipole material.

According to another aspect of the present disclosure, there is provided a display apparatus. The display apparatus comprises a substrate having a plurality of sub-pixels defined, a plurality of light-emitting elements disposed in each of the plurality of sub-pixels, a plurality of first driving electrodes disposed on one side of the plurality of light-emitting elements on the plurality of light-emitting elements, a plurality of second driving electrodes disposed on the other side of the plurality of light-emitting elements on the plurality of light-emitting elements, and a plurality of optical members covering a portion of top surfaces of the plurality of first driving electrodes and a portion of top surfaces of the plurality of second driving electrodes, and configured to shift their shapes one side or the other side depending on a voltage applied to the plurality of first driving electrodes and the plurality of second driving electrodes.

The plurality of first driving electrodes and the plurality of second driving electrodes can be disposed to be spaced apart from each other along a first direction with the plurality of light-emitting elements therebetween, and each of the plurality of first driving electrodes and the plurality of second driving electrodes can extend along a second direction.

The plurality of optical members can extend in the second direction.

In the plurality of first driving electrodes and the plurality of second driving electrodes, the plurality of optical members can be shifted in a direction of a driving electrode in which a high voltage is applied.

The display apparatus can further comprise an encapsulating layer disposed on the plurality of light-emitting elements, wherein the plurality of first driving electrodes and the plurality of second driving electrodes can be disposed on the encapsulating layer.

The display apparatus can further comprise a plurality of first transistors and a plurality of second transistors which are disposed on the encapsulating layer and include a semiconductor layer, a gate electrode, a source electrode, and a drain electrode, wherein the plurality of first driving electrodes can be connected to the plurality of first transistors, respectively, and the plurality of second driving electrodes can be connected to the plurality of second transistors, respectively.

The display apparatus can further comprise a black matrix overlapping the semiconductor layer of the plurality of first transistors and the semiconductor layer of the plurality of second transistors on the encapsulating layer.

The display apparatus can further comprise a touch sensing unit including a bridge electrode and a touch electrode on the encapsulating layer, wherein the gate electrode of the plurality of first transistors and the gate electrode of the plurality of second transistors can be disposed on a same layer as the bridge electrodes, and the source electrode of the plurality of first transistors, the drain electrode of the plurality of first transistors, the source electrode of the plurality of second transistors, and the drain electrode of the plurality of second transistors can be disposed on a same layer as the touch electrode.

The plurality of optical members can include a polymer-stabilized liquid crystal (PSLC).

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a substrate having a plurality of sub-pixels;
a plurality of light-emitting elements disposed in the plurality of sub-pixels;
an encapsulating layer disposed on the plurality of light-emitting elements;
a plurality of optical members disposed on the encapsulating layer for each of the plurality of sub-pixels;
a plurality of first transistors disposed on the encapsulating layer;
a plurality of second transistors disposed on the encapsulating layer;
a plurality of first driving electrodes connected to the plurality of first transistors on the encapsulating layer and in contact with one side of the plurality of optical members; and
a plurality of second driving electrodes connected to the plurality of second transistors on the encapsulating layer and in contact with another side of the plurality of optical members.

2. The display apparatus according to claim 1, wherein the plurality of first driving electrodes and the plurality of second driving electrodes are disposed to be spaced apart from each other along a first direction with the plurality of light-emitting elements interposed between the plurality of first driving electrodes and the plurality of second driving electrodes.

3. The display apparatus according to claim 2, wherein the plurality of optical members is in a shape of bars extending in a second direction different from the first direction.

4. The display apparatus according to claim 1, wherein in the plurality of first driving electrodes and the plurality of second driving electrodes, the plurality of optical members is configured to be shifted in a direction of a driving electrode in which a high potential voltage is applied.

5. The display apparatus according to claim 1, wherein the plurality of optical members is symmetrical with respect to a central axis when the plurality of first transistors and the plurality of second transistors are turned off.

6. The display apparatus according to claim 1, further comprising:
a bridge electrode disposed on the encapsulating layer; and
a touch electrode disposed on the bridge electrode,
wherein the plurality of first driving electrodes and the plurality of second driving electrodes are disposed on a same layer as the touch electrode.

7. The display apparatus according to claim 1, further comprising:
a black matrix disposed between the encapsulating layer and the plurality of first transistors and disposed between the encapsulating layer and the plurality of second transistors.

8. The display apparatus according to claim 1, further comprising:
an insulating layer disposed on the plurality of first transistors and the plurality of second transistors;
a plurality of first signal lines disposed on the insulating layer and connected to the plurality of first transistors;
a plurality of first enable lines disposed on the insulating layer and connected to the plurality of first transistors;
a plurality of second signal lines disposed on the insulating layer and connected to the plurality of second transistors; and
a plurality of second enable lines disposed on the insulating layer and connected to the plurality of second transistors.

9. The display apparatus according to claim 1, wherein the plurality of optical members includes a dipole material.

10. The display apparatus according to claim 1, wherein a shape of the plurality of optical members is varied to provide a plurality of different viewing angles.

11. A display apparatus comprising:
a substrate having a plurality of sub-pixels;
a plurality of light-emitting elements disposed in the plurality of sub-pixels;
a plurality of first driving electrodes disposed on one side of the plurality of light-emitting elements;
a plurality of second driving electrodes disposed on another side of the plurality of light-emitting elements; and
a plurality of optical members covering a portion of top surfaces of the plurality of first driving electrodes and a portion of top surfaces of the plurality of second driving electrodes, and configured to shift shapes of the plurality of optical members towards one side or another side of the plurality of optical members depending on a voltage applied to at least one of the plurality of first driving electrodes and the plurality of second driving electrodes.

12. The display apparatus according to claim 11, wherein the plurality of first driving electrodes and the plurality of second driving electrodes are disposed to be spaced apart from each other along a first direction with the plurality of light-emitting elements interposed between the plurality of first driving electrodes and the plurality of second driving electrodes, and
wherein each of the plurality of first driving electrodes and the plurality of second driving electrodes extends along a second direction different from the first direction.

13. The display apparatus according to claim 12, wherein the plurality of optical members extends in the second direction.

14. The display apparatus according to claim 11, wherein in the plurality of first driving electrodes and the plurality of second driving electrodes, the plurality of optical members is shifted in a direction of a driving electrode in which a high voltage is applied.

15. The display apparatus according to claim 11, further comprising:
an encapsulating layer disposed on the plurality of light-emitting elements,
wherein the plurality of first driving electrodes and the plurality of second driving electrodes are disposed on the encapsulating layer.

16. The display apparatus according to claim 15, further comprising:
a plurality of first transistors and a plurality of second transistors disposed on the encapsulating layer,
wherein each of the plurality of first transistors and the plurality of second transistors includes a semiconductor layer, a gate electrode, a source electrode, and a drain electrode,
wherein the plurality of first driving electrodes is connected to the plurality of first transistors, respectively, and
wherein the plurality of second driving electrodes is connected to the plurality of second transistors, respectively.

17. The display apparatus according to claim 16, further comprising:
a black matrix overlapping the semiconductor layer of the plurality of first transistors and the semiconductor layer of the plurality of second transistors on the encapsulating layer.

18. The display apparatus according to claim 16, further comprising:
a touch sensing unit including a bridge electrode and a touch electrode on the encapsulating layer,
wherein the gate electrode of the plurality of first transistors and the gate electrode of the plurality of second transistors are disposed on a same layer as the bridge electrodes, and
wherein the source electrode of the plurality of first transistors, the drain electrode of the plurality of first transistors, the source electrode of the plurality of second transistors, and the drain electrode of the plurality of second transistors are disposed on a same layer as the touch electrode.

19. The display apparatus according to claim 11, wherein the plurality of optical members includes a polymer-stabilized liquid crystal (PSLC).

20. The display apparatus according to claim 11, wherein the plurality of optical members is in a shape of bars extending in a same direction as an extension direction of a light-emitting area of the plurality of subpixels.
